(19) United States
(12) Patent Application Publication
(10) Pub. No.: US 2010/0319764 A1
(43) Pub. Date: Dec. 23, 2010

(54) Functional Integration Of Dilute Nitrides Into High Efficiency III-V Solar Cells

(75) Inventors: Michael W. Wiemer, Campbell, CA (US); Homan B. Yuen, Sunnyvale, CA (US); Vijit A. Sabnis, Cupertino, CA (US); Michael J. Sheldon, San Jose, CA (US); Ilya Fushman, Palo Alto, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Solar Junction Corp., San Jose, CA (US)

(21) Appl. No.: 12/819,534

(22) Filed: Jun. 21, 2010

Related U.S. Application Data
(60) Provisional application No. 61/219,485, filed on Jun. 23, 2009.

(51) Int. Cl. H01L 31/0304; H01L 31/18

(52) U.S. Cl. 136/255; 438/93; 257/E31.019

(57) ABSTRACT

Tunnel junctions are improved by providing a rare earth-Group V interlayer such as erbium arsenide (ErAs) to yield a mid-gap state-assisted tunnel diode structure. Such tunnel junctions survive thermal energy conditions (time/temperature) in the range required for dilute nitride material integration into III-V multi-junction solar cells.

### CROSS-REFERENCES TO RELATED APPLICATIONS

Not Applicable

### STATEMENT AS TO RIGHTS TO INVENTIONS MADE UNDER FEDERALLY SPONSORED RESEARCH AND DEVELOPMENT

Not Applicable

### REFERENCE TO A “SEQUENCE LISTING,” A TABLE, OR A COMPUTER PROGRAM LISTING APPENDIX SUBMITTED ON A COMPACT DISK

Not Applicable

### BACKGROUND OF THE INVENTION

This invention relates to photo-voltaic solar cell technology and in particular to the process for constructing high efficiency multi junction III-V solar cells.

A III-V solar cell is formed by integrating various sub-cells together in a single layered structure into a single functioning solar cell. Each of the sub-cells absorbs light in different regions of the solar spectrum and convert that light into current and voltage. These sub-cells are electrically connected by sub-structures called tunnel junctions. Each of these sub-structures impacts the overall performance of the solar cell, and integration is not trivial. For example, in a conventional triple junction cell, there are 5 sub-structures: three light absorbing sub-cells and two tunnel junctions (TJs) (see FIG. 1). All of these sub-elements must integrate well together.

By properly choosing the band gaps of the sub-cells used in a III-V solar cell, it is possible to optimize the cell's overall conversion efficiency (See J. F. Geisz, D. J. Friedman, J. S. Ward, A. Duda, W. J. Olavarria, T. E. Moriarty, J. T. Kiehl, M. J. Romero, A. G. Norman, K. M. Jones, “40.8% efficient inverted triple junction solar cell with two independently metamorphic junctions,” Appl. Phys. Lett. Vol. 93, No. 123505, 2008). It is well known that a triple-junction III-V solar cell with a ˜1 eV band gap sub-cell sand that is lattice matched to GaAs, could have improved efficiency over a conventional triple junction III-V solar cell (i.e. a solar cell with a Germanium based bottom junction). In fact, a material system with a tunable band gap less than that of GaAs (1.42 eV) would be preferred for creating solar cells with three or more junctions. One of the main material systems which has been considered for this role is the dilute nitride material system (generally described as GaInNAs, possibly with small amounts of Sb or Bi. See for example K. Volz, J. Koch, B. Kunert, I. Nemeth, W. Soltz, “Influence of annealing on the optical and structural properties of N-containing III/V semiconductor heterostructures”, J. of Crystal Growth, Vol. 298, pp 126-130, 2007). Hereinafter these types of materials will be referred to simply as dilute nitrides. This material system appears to be suitable for integration into a solar cell because it can be latticed matched to GaAs independently of its band gap, for band gaps<1.42 eV. Dilute nitrides in tunnel junctions are known in other contexts, such as LEDs. See for example U.S. Pat. No. 6,765,238.

However, the integration of dilute nitride materials into a solar cell requires more than lattice matching. Other integration considerations are required in order to successfully use this material in a high performance III-V solar cell. To date, it has not been shown how to solve these integration problems to create a high performance dilute nitride sub-cell in a multi-junction solar cell without destroying the performance of other sub-cells, sub-structures, or the solar cell as a whole.

### Multi-Junction Solar Cell Integration Requirements

a. Lattice Matching

It is known that the dilute nitride material system (with or without small amounts of Sb or Bi) can be grown lattice matched to GaAs by properly choosing the material composition. In fact, by trading off the relative compositional weighting of the elements in the compound in the layer, such as indium and nitrogen, one can tune the band gap of the dilute nitride material while maintaining lattice matching. Lattice matched materials typically do not have crystalline defects at the levels that occur during non-lattice-matched growth. These defects can both harm device performance and device reliability.

b. Current Matching

Another basic sub-cell parameter which must be evaluated to see if a sub-cell is to be integrated into a multi junction device is its current density (J_{sc}). In order to efficiently integrate a dilute nitride sub-cell into a multi junction solar cell, it must produce a current equal to or greater than the other sub-cells in the device (e.g. GaAs and InGaP based sub-cells). Since all the sub-cells are connected together in series through tunnel junctions, the currents flowing through all sub-cells must be identical (see FIG. 2). Thus, all the sub-cells must generate approximately the same amount of current in order to convert the solar spectrum with optimal efficiency (i.e., they must be “current matched”).

For a typical triple junction device using GaAs and InGaP as the other two sub-cell materials under AM1.5D solar radiation, a dilute nitride sub-cell must produce a current greater than about 13 mA/cm² at a 1-sun concentration in order to achieve current matching. As further motivation for a high current generating low band gap cell, it may be advantageous to have the low band gap cell produce more current than is required, at the expense of some overall solar cell efficiency. For example, having the bottom cell produce more current than is required for current matching relaxes the optical transfer function constraint placed on systems integrators. In this case, systems integrators can focus on keeping a system's optical throughput high in the spectral range covered by the (e.g.) GaAs and InGaP sub-cells, while relaxing the throughput constraint of the bottom sub-cell.

Despite its predicted benefits to solar cell efficiency, dilute nitrides are not used in commercial III-V solar cells because producing dilute nitride sub-cells with the proper band gap that also produce currents high enough to achieve current matching has been extremely challenging. There is only one known report where the required current level has been achieved (>13 mA/cm²) (D. B. Jackrel, S. R. Bank, H. B. Yuen, M. A. Wistey, J. S. Harris, A. J. Ptak, S. W. Johnston, D. J. Friedman, S. R. Kurtz, “Dilute nitride GaInNAs and GaInNAsSb solar cells by molecular beam epitaxy”, J. Appl. Phys, Vol. 101, No. 114916, 2007).

One key to achieving the required performance is to subject the dilute nitride sub-cell to a thermal annealing step. All elevated temperatures seen by the dilute nitride material after its deposition may affect the dilute nitride layer's properties. The temperature and time required to grow additional solar cell layers on top of a dilute nitride layer can also be considered part of the dilute nitride annealing process. Generally, the temperatures and times used for additional growth on top of the dilute nitride layer are not sufficient to improve the parameters of the dilute nitride to the fullest extent. As such, annealing the dilute nitride material after complete epitaxial deposition of the solar cell tends to improve the dilute nitride sub-cell's parameters significantly, making it possible to successfully integrate such a sub-cell into a multi junction cell. According to published literature, dilute nitride annealing has been performed over a very wide range of times and temperatures by various researchers and entities. While not every time/temperature combination optimally improves the performance of dilute nitride based devices, annealing examples from the literature range from 525° C. to 800° C. for up to 2 hours (per K. Voltz, D. Lackner, I. Nemeth, B. Kunert, W. Stolz, C. Bauer, F. Dimroth, A. W. Bett, “Optimization of annealing conditions of (GaIn)(NAs) for solar cell applications”, Journal of Crystal Growth, 310, pp. 2222-2228, 2008), and >800° C. for shorter periods of time (e.g. 30 seconds to one minute or more) (J. Miguel-Sanchez, A. Guzman, J. M. Ulloa, A. Hierro, E. Munoz, “Effect of nitrogen on the optical properties of InGaAsN p-i-n structures grown on misoriented (111)B GaAs substrates”, Appl. Phys. Lett., Vol. 84, No. 14, pp. 2524-2526, 2004).

c. Fully Integrated Device Must Withstand Thermal Anneal

It is not enough to make a good stand-alone dilute nitride sub-cell. It is also necessary to integrate the dilute nitride sub-cell into a fully functional multi junction device. While the lattice matching and band gap constraints can be met by using the proper composition of dilute nitride, the performance of the sub-cell can be improved through annealing (See U.S. patent application Ser. No. 12/217,818 by J. S. Harris et. al.). The thermal dose seen by the GaInNAs sub-cell to improve its performance may be done in-situ, ex-situ, or a combination of both, with respect to the deposition chamber in which the materials are deposited. While beneficial to the GaInNAs sub-cell, the application of the thermal load (or dose) to the dilute nitride sub-cell (or cells) may adversely affect the other sub-structures dramatically. In order to use dilute nitrides in a multi junction cell, these other sub-structures must be engineered to withstand the dilute nitride annealing step. This annealing constraint is unique to multi-junction cells incorporating dilute nitride material. Solar cells without a dilute nitride sub-cell do not have this constraint. As an example of a conventional solar cell without a dilute nitride sub-cell, see FIG. 1.

While the other common types of sub-cells (e.g. GaAs and InGaP) generally show little degradation after annealing (e.g., no catastrophic failure), typical tunnel junctions degrade significantly, even catastrophically, after a dilute nitride anneal. (See S. Ahmed, M. R. Melloch, E. S. Harmon, D. T. Mclnturff, J. M. Woodall, “Use of nonstoichiometry to form GaAs tunnel junctions”, Appl. Phys. Lett., Vol. 72 No 25, pp 3667-3369, 1997). In addition, FIG. 8 shows two Current (I) vs. Voltage (V) curves from multi junction solar cell devices measured at around 820 suns. The curves come from two different wafers with identical epitaxial stacks. The tunnel junction design used was an n-GaAs/p-AlGaAs type design (no ErAs). One wafer was annealed at 780 C (Curve 1, black) and the other was annealed at 740 C (Curve 2, grey). The anneal time for both wafers was identical. One can clearly see that the wafer which got the hotter anneal exhibits a clear tunnel junction failure. Tunnel junction failures of this type limit the range of anneal thermal load (e.g. the times and temperatures) one can apply to the solar cell stack to improve the performance of the GaInNAs sub-cell.

### Tunnel Junction Background

By creating an abrupt p++/n++junction as indicated by the energy level diagram shown in FIG. 3, one can create a condition whereby band-to-band tunneling occurs. This tunneling is dependent on the high electric field caused by the abrupt transition of the doping from highly p-type to highly n-type. In such a device, the p-n junction displays a current-voltage characteristic around zero volts, very much like a resistor, and connects the p-side of one sub-cell with the n-side of an adjacent sub-cell. The parameters of interest for such a tunnel junction inside a multi junction solar cell are shown in FIG. 5, which are:
1.) Low Effective Resistance at the Operating Point (ideally ≦1 mΩ/cm2, but practically <5 mΩ/cm2)
   a. Effective Resistance, R, is defined as the voltage drop Vₒₚ, at the operating current Iₒₚ, or in other words, V_{Op}(I_{Op}), divided by the operating current. This is not the slope resistance at the operating point.

R=V_{Op}(I_{Op})/I_{Op} (0.1)
b. For a triple junction solar cell at 500× concentration, Iₒₚ is around 7.5 A/cm². Other concentration levels result in other operating currents, as do other multi-junction designs with different band gap combinations or numbers of band gaps.
2.) Low Optical Absorption (ideally <1% of the incident light)

As the doping levels increase on both sides of the junction, or as the band gap is lowered, the tunneling current, Jₜ, increases (see Eq. (0.2) for an approximation of an abrupt junction where N_{A} is the acceptor doping, N_{D} is the donor doping, and E_{g} is the band gap).

Jₜ∝exp(−(N_{A}+N_{D})/N_{A}N_{D}) (0.2)

From Equation (0.2) we can see that the tunneling current increases as the doping level increases. However, it is difficult to achieve n-type doping above about 5e18 cm⁻³ with the standard silicon dopant. It is particularly difficult to maintain activated doping levels above 5e18 cm⁻³ Silicon post anneal. Silicon doping levels in GaAs which are higher than about 5e18 cm⁻³ tend to pin around 5e18 cm⁻³ after anneal. (See Table 1).

TABLE 1
Activated Silicon Dopant Levels in GaAs before
and after dilute nitride material anneal.

| | Pre Anneal | Post Anneal |
|---|---|---|
| Activated Silicon Dopant | 1e19 cm⁻³ | 5e18 cm⁻³ |

To achieve higher n-type doping levels, many people use Te or Se. While these dopants have higher activated solubility in GaAs based materials, they diffuse rapidly when the doping is high and they are subjected to temperatures in the range of the dilute nitride material anneal. Likewise, when beryllium is used as a p-type dopant, dopant diffusion under thermal processes is again detrimental. Moreover, dopant diffusion is generally enhanced as the doping level is increased, and the high field region of the tunnel junction can cause field enhanced dopant diffusion. As the dopants in a tunnel junction diffuse, they wash out the abruptness of the junction and thereby reduce the electric field. This negatively impacts the tunneling behavior of the device both increasing its resistance and decreasing its peak current density. If the diffusion is large enough, tunneling behavior can disappear entirely. Thus, tunnel junctions based on high doping levels are inherently susceptible to degradation, as for example by thermal annealing.

Ahmed et al. studied the effects of annealing on low temperature grown GaAs tunnel junctions (S. Ahmed, M. R. Melloch, E. S. Harmon, D. T. Mclnturff, J. M. Woodall, “Use of nonstoichiometry to form GaAs tunnel junctions”, Appl. Phys. Lett., Vol. 72 No. 25, pp 3667-3369, 1997). According to the authors, before annealing, the tunnel junctions performed remarkably well, while after annealing, the tunnel diode characteristics degrade significantly. In fact, the tunnel diodes annealed at 800° C. for 30 seconds (well within the range for dilute nitride annealing) barely meet the required specifications for integration into multi junction solar cells. This degradation is typical of all tunnel diodes based on high, abrupt doping levels. However, according to Ahmed et al., the tunneling is enhanced by low temperature grown GaAs defects in the tunnel junction (mid-gap states). For multi junction solar cells, it is undesirable to insert crystal defects intentionally into the III-V material epi layer stack as these defects may cause reliability problems over time. Additionally, yield problems may occur if the defective material in the tunnel junction inhibits reliable formation of high quality (low defect) material grown on top of the tunnel junction. Finally, as stated above in the section on “Current Matching,” the dilute nitride material annealing step may require anneal times to be longer and temperatures higher than the 30 seconds at 800° C. used by Ahmed. These more aggressive anneal conditions would cause such tunnel junctions to degrade below the required performance levels for high concentration III-V solar cells.

In addition, a tunnel junction is preferred to be constructed from band gaps larger than the largest band gap of any subcell beneath the tunnel junction. Using high band gap materials reduces optical absorption in the tunnel junction and increases overall solar cell efficiency. However, as can be seen in Equation (0.2), higher band gap tunnel junctions exhibit lower tunneling current for the same bias voltage (higher tunnel resistance) making anneal survivability that much more difficult. In addition, large band gap materials typically have lower activated dopant maximums.

The insertion of layers providing mid-gap states into the middle of a tunnel junction diode is known, as it enables tunneling to occur by a two-step process. For example, insertion of a rare earth-Group V combination such as ErAs between the p+ layer and the n+ layer provides mid-gap states, which effectively reduces the tunnel barrier magnitude. See for example, J. M. O. Zide, A. Kleiman-Shwarsctein, N. C. Strandwitz, J. D. Zimmerman, T. Steenblock-Smith, A. C. Gossard, “Increased efficiency in multijunction solar cells through the incorporation of semimetallic ErAs nanoparticles into the tunnel junction”, Appl. Phys. Lett., Vol. 88, No. 162103, 2006, or see U.S. Pat. Publication No. 2007/0227588 aka Ser. No. 11/675,269 of Gossard et al. However, heretofore, there have not been any reports as to the thermal stability of such tunnel junctions in a multi junction device.

For the foregoing reasons, a new approach is needed for improving the efficiency of multi junction solar cells which utilize a dilute nitride layer.

### SUMMARY OF THE INVENTION

According to the invention, in a multi junction solar cell composed of III-V materials, including a dilute nitride subcell, additional layers of material effecting mid-gap states are inserted into one or more of the tunnel junctions in a manner to achieve a tunnel junction design that is thermally stable and exhibits good performance after extraordinary thermal annealing times and temperatures required by the dilute nitride material in the solar cell. An appropriate thermal energy dose or loading can be effected in an number of ways such as by heating the entire structure, and it may include adding an additional thermal step that causes annealing of the entire structure, even though it is detrimental to a conventional tunnel junction. According to the invention, the additional layers that transform the tunnel junction are composed of erbium arsenide (ErAs), which has been found to retain its favorable properties after thermal energy loading. The dependence of the tunneling behavior on doping level and the abruptness of the p-to-n doping change is thereby reduced by insertion of such layers, and good performance is achieved even after being subjected to the thermal energy that is necessary to achieve improved properties of the dilute nitride material.

The invention will be better understood by reference to the following detailed description in connection with the accompanying drawings.

### BRIEF DESCRIPTION OF THE DRAWINGS

FIG. 1 is a side cross-sectional view in schematic form of a conventional (prior art) III-V solar cell.

FIG. 2 is a side cross-sectional view in schematic form of a high-performance III-V solar cell with a dilute nitride (prior art).

FIG. 3 is p++ n++ junction energy band diagram with voltage bias showing tunneling across the band gap (prior art).

FIG. 4(a) is an energy band diagram of a conventional (prior art) diode of the prior art wherein there is no state for an electron to tunnel into.

FIG. 4(b) is an energy band diagram of an ErAs mid-gap-state-assisted tunnel diode as employed in connection with an annealed dilute nitride type multi junction solar cell according to the invention.

FIG. 5 is a V-I diagram for types of tunnel junctions based on high doping and abruptness—e.g., an unannealed standard type where the tunnel junction which meets the desired specifications (solid line), together with a tunnel junction based on mid-gap states and high doping and abruptness (dashed line 1) and a tunnel junction based on mid-gap states and lower doping and abruptness (dashed line 2).

FIG. 6 is a voltage-current diagram of ErAs tunnel junctions before (Curve 1) and after (Curve 2) dilute nitride material anneal at 780 C for 1 min, showing that ErAs tunnel junctions do not degrade significantly after anneal, maintaining high peak current density.

FIG. 7 is a cross-sectional view in schematic form of one embodiment of an ErAs tunnel junction structure from a III-V multi junction solar cell according to the invention.

FIG. 8 Current (I) vs. Voltage (V) curves of devices from two wafers with identical growths but different anneal temperatures showing failure of the tunnel junction at the higher anneal temperature.

FIG. 9 Current (I) vs. voltage (V) curve of an annealed multi junction solar cell using an ErAs tunnel junction measured at approximately 820 suns.

### DETAILED DESCRIPTION OF THE INVENTION

Referring to FIG. 4(b), the operation of a tunnel junction with erbium arsenide is illustrated. The operation comprises, first, the tunneling of electronic carriers from the higher potential n+ state of a III-V material into a thin interlayer of rare earth-Group V material, particularly erbium arsenide (ErAs), then second, the tunneling of electrons from the mid potential of the rare-earth-Group V material into the lower potential p+ state of a III-V material, such as gallium arsenide (GaAs).

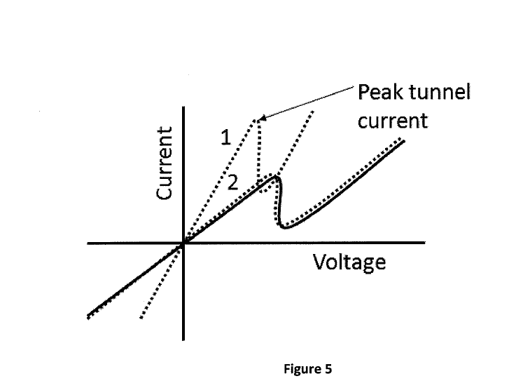

Thus electronic carriers have only to tunnel through a small barrier into the mid-gap state, then through a small barrier out of the mid-gap state. This reduction in tunnel barrier magnitude increases the tunnel current for a given applied bias. (See FIG. 5, dashed curve 1). The lowering of the tunnel barrier magnitude is also useful when making tunnel junctions out of higher band gap materials.

For a desired current level through a tunnel junction incorporating mid-gap states (see FIG. 5, dashed curve 1), less bias, i.e., less electric field, is required than a tunnel junction with no mid-gap states (see FIG. 5, solid curve). The reduction in the required electric field means that for the same bias voltage as a device without mid-gap states, the mid-gap state device can use lower doping and/or lower junction abruptness to achieve the same current. Thus a device with mid-gap states is expected to achieve a similar resistance and peak tunnel current using lower doping and abruptness (see FIG. 5, dashed curve 2), as a device with higher doping and abruptness but no mid-gap states (see FIG. 5, solid curve).

Such mid-gap states can be created through the use of rare earth nanoparticles, such as ErAs inserted into the tunnel junction (see FIGS. 4a and 4b). When for example the rare earth-Group V combination ErAs is deposited on GaAs in thin layers, it balls up into nanoparticle islands. These islands are so small and discontinuous that it is possible to continue overgrowth of GaAs while maintaining GaAs lattice matching. Photomicrographic analysis using cross-sectional transmission electron microscopy (TEM) of ErAs nanoparticles in GaAs shows that the lattice is continuous across the ErAs interface, namely that the GaAs crystal retains registry, even after extraordinary heating, such as caused by annealing. In addition, the optical wavelength absorption of the ErAs layers is quite small, making them ideal for solar cell integration.

Use of other rare earth-Group V compounds is also possible to achieve the same effect. While other work has shown the effect of ErAs on tunnel junction electrical behavior and the fact that the nano-island layers cause little optical absorption, no work has shown the thermal stability of ErAs enhanced tunnel junctions, nor whether ErAs enhanced tunnel junctions are effective in a III-V solar cell containing a dilute nitride layer. The present invention has determined that ErAs enhanced tunnel junctions are in fact thermally stable after the annealing that is required to modify, i.e., enhance dilute nitride layer performance.

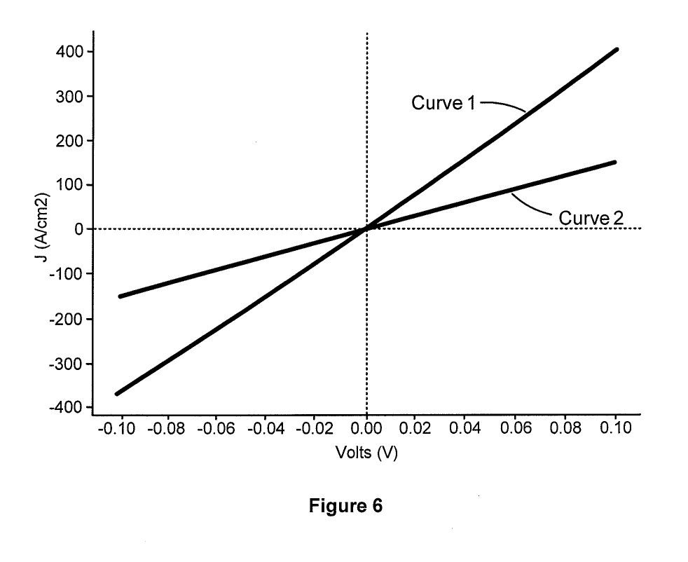

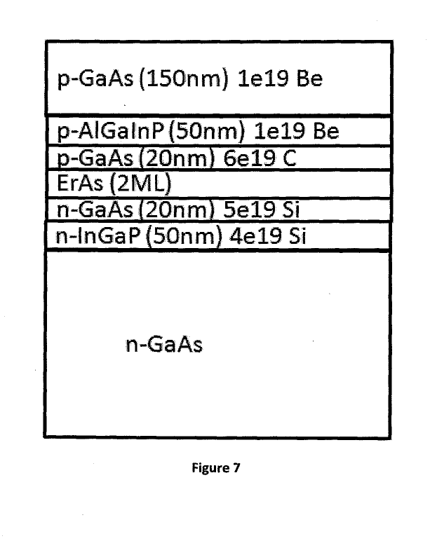

FIG. 6 and Table 1 demonstrate that ErAs enhanced tunnel junctions embedded in GaAs based material can survive the thermal processes associated with a dilute nitride sub-cell layer. Curve 1 is the V-I characteristic of the ErAs tunnel junction before heating and Curve 2 is the V-I characteristic of the ErAs tunnel junction after heating needed to enhance the dilute nitride layer. Notably, the resistance merely changes, as indicated by the change in slope (or voltage drop), and there is no “peak current density” within the current range tested at which the current decreases with voltage (or that this tunnel diode fails to operate). In contrast, non-ErAs-type tunnel junctions appear to fail or have drastically reduced peak current densities. Here, if the resistance is not large, the difference can be ignored. The ErAs layer in FIG. 6 and Table 1 was grown similarly to those described in the dissertation of J. D. Zimmerman, “Growth and use of epitaxially grown ErAs semimetal to enhance III-V Schottky diode and tunnel junction performance”, (Ph.D. Dissertation, University of California Santa Barbara, March 2008) and by Kadow et al. (C. Kadow, S. B. Fleischer, J. P. Ibbetson, J. E. Bowers, and A. C. Gossard, Appl. Phys. Lett., 75, 3548 1999). The ErAs tunnel junction device structure relevant to FIG. 6 and Table 1 is shown in FIG. 7, which includes an ErAs layer of 2 mono-layer thickness. All other layers are essentially conventional. In FIG. 6, the annealing conditions were 780° C. for 1 min in a rapid thermal annealer (RTA). A suitable range of optimal annealing temperatures for the GaInNAs (dilute nitride) material used in multi junction cells is from 500° C. to 900° C. for anneal times between several hours, with substantially less time needed at higher anneal temperatures.

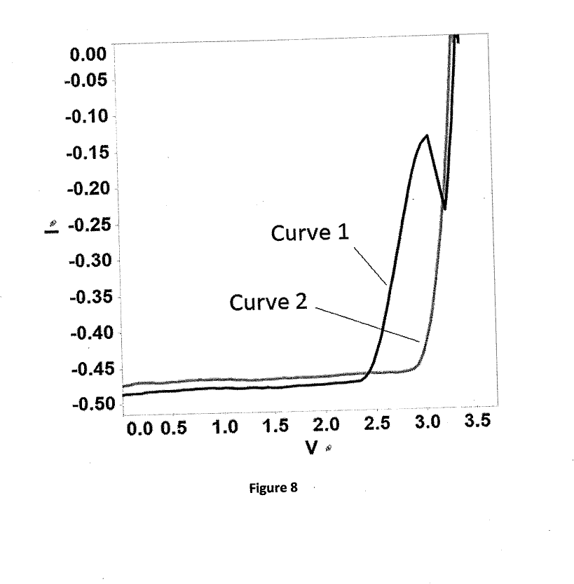

In a triple junction solar cell under 500× concentration, the tunnel junctions must be capable of conducting approximately 7.5 A/cm². The tunnel junctions in FIG. 6 can maintain peak current densities far beyond those required for triple junction cells. In addition, the resistivity is <1 mOhm/cm², which also far exceeds the desired specifications for integration into multi junction solar cells. It is expected that substantially all lanthanide series rare earth elements (elements 57 through 71 of the Periodic Table) are suitable in one form or another for incorporation in a rare-earth-Group V diode. However, erbium with arsenic and erbium with phosphorus are the current preferred rare earth elements and Group V elements in a compound-containing diode device. Other erbium-based compounds may also be effective, but as yet are unproven. These included erbium with antimony, bismuth and nitrogen. It is expected that this ErAs tunnel junction approach will allow most if not all of the GaInNAs optimal anneal range to be explored and applied to multi junction solar cells utilizing at least one GaInNAs sub-cell, without tunnel junction failure like that shown in FIG. 8.

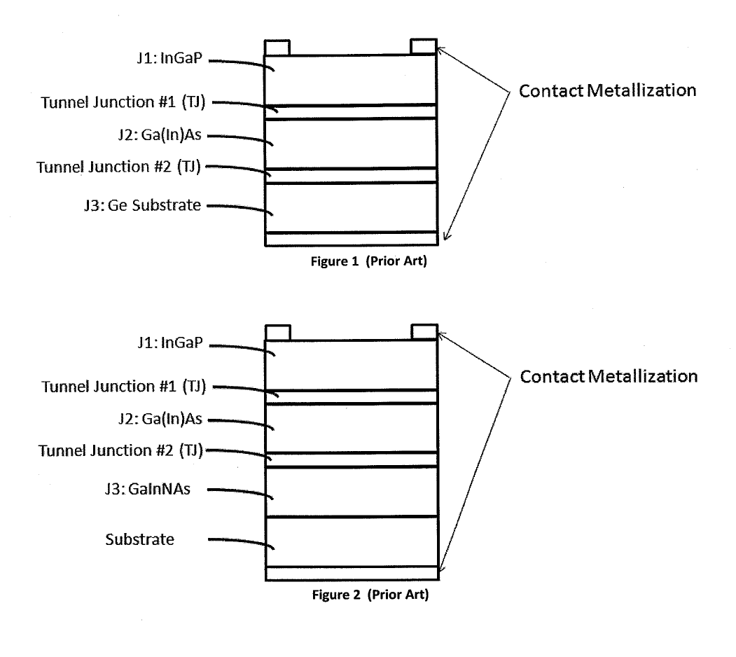

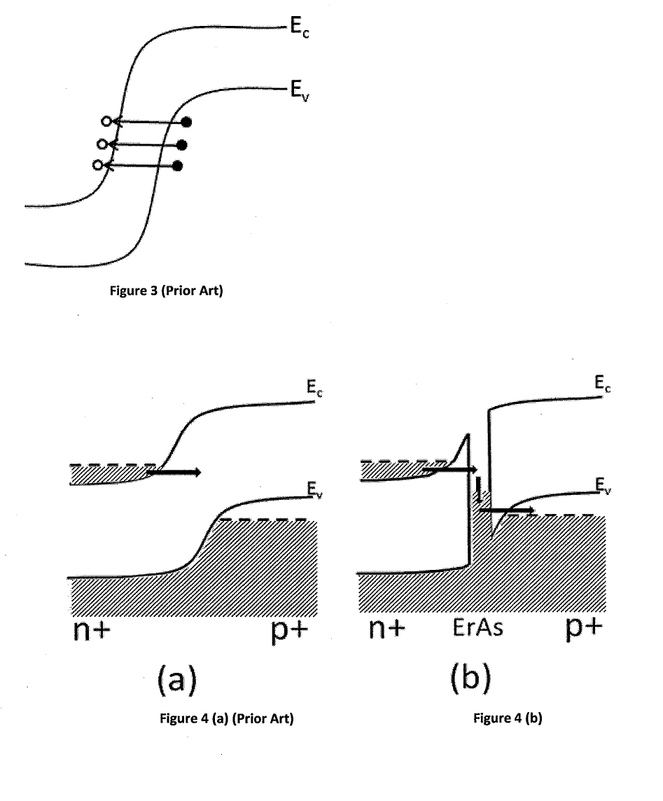

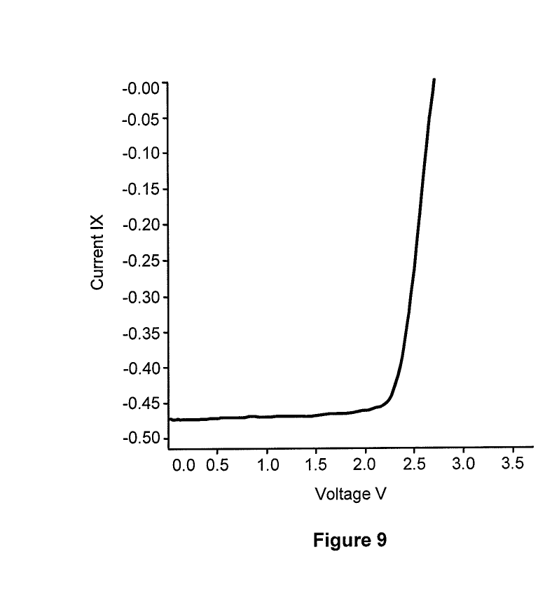

The exemplary device structure shown in FIG. 7 exhibits low optical absorption when used as a tunnel junction directly on top of sub-cells which have band gaps smaller than that of GaAs (for example, as “Tunnel Junction #1” in FIG. 1 and FIG. 2). The top-most layer of p-GaAs in FIG. 7 is not required in a multi-junction cell and is only there to facilitate electrical testing of the tunnel junction directly. However, the two 20 nm layers of p-GaAs and n-GaAs material surrounding the ErAs layer would appear in an integrated solar cell. This 40 nm of GaAs can cause undesired optical absorption if this tunnel junction were used to connect sub-cells with band gaps larger than or equal to GaAs. In this case, the tunnel junction would act like a filter, absorbing some of the light passing through it. The solution to this problem is to make one or more of the layers, either the p+ layer, the n+ layer or both, surrounding the ErAs containing interlayer out of higher band gap materials. Such materials may be GaAs, AlGaAs, AlGaInP, GaInP, GaInAs or AlGaInAsP. In other words: gallium arsenide, aluminum indium gallium phosphide, indium gallium phosphide, aluminum gallium arsenide, gallium indium arsenide, or aluminum gallium indium arsenide phosphide. In the case of phosphide based materials, the role of ErAs is served by ErP. Dilute nitrides may also populate the tunnel junction. These include GaInNAs alone, or with Bi, Sb, or a combination of both, namely, GaInNAs, GaInNAsSb, GaInNAsBi, or GaInNAsSbBi. It has been demonstrated that high concentration multi junction solar cells perform well post-high temperature anneal (no Tunnel Junction failures up to and beyond 820 suns) utilizing higher band gap materials in the tunnel junction. These solar cells utilize tunnel junctions with a p-AlGaAs/ErAs/n-GaAs design. The higher band gap p-AlGaAs side of the tunnel junction increases the optical transmission of the tunnel junction sub-structure. FIG. 9 shows an I-V curve from just such a device. The anneal temperature was 850° C. and the anneal time was less than half of that of the devices shown in FIG. 8.

TABLE 2
ErAs tunnel junction performance before and after anneal.

| | Peak Tunnel | Effective Resistance |
|---|---|---|
| | Current | at 7.5 A/cm2 |
| No Anneal | >400 A/cm2 | 0.25 mΩ/cm2 |
| Anneal | >150 A/cm2 | 0.80 mΩ/cm2 |

In summary, tunnel junctions having a rare earth-Group V interlayer survive annealing conditions (time/temperature) in the range required for dilute nitride material integration into III-V multi-junction solar cells. The mid-gap states created by the ErAs, and ErAs's apparently inherit thermal stability, reduce the dependence of the tunnel junction on high, abrupt doping levels, rendering it less susceptible to thermal degradation.

The invention has been explained with reference to specific embodiments. Other embodiments will be evident to those of ordinary skill in the art. It is therefore not intended that this invention be limited, except as indicated by appended claims.

What is claimed is:

1. A process for forming a III-V multi junction solar cell including forming a tunnel junction in the solar cell, the process comprising:
providing at least one layer containing a dilute nitride in the multi junction solar cell;
providing an n+ semiconductor layer associated with a tunnel junction;
providing a p+ semiconductor layer confronting the n+ semiconductor layer; and
providing a rare earth-Group V interlayer between the p+ layer and the n+ layer that forms a mid-gap-state-assisted tunnel diode; and
enhancing the dilute nitride layer to improve performance of the solar cell.

2. The process according to claim 1, the enhancing step comprising:
applying thermal energy to the multi junction solar cell sufficient to modify the voltage and current properties of the dilute nitride layer.

3. The process according to claim 1 wherein the n+ layer is a III-V-based compound.

4. The process according to claim 3 wherein the p+ layer is a III-V-based compound.

5. The process according to claim 4 wherein the rare earth-Group V interlayer is an erbium-based compound.

6. The process according to claim 1 wherein the rare earth-Group V interlayer is a compound of a lanthanide and a Group V element.

7. The process according to claim 1 wherein the n+ layer is a dilute nitride.

8. The process according to claim 1 wherein the n+ layer is selected from the group consisting of GaInNAs, GaInNAsSb, GaInNAsBi, and GaInNAsSbBi as a dilute nitride.

9. The process according to claim 1 wherein the p+ layer is a dilute nitride.

10. The process according to claim 1 wherein the p+ layer is selected from the group consisting of GaInNAs, GaInNAsSb, GaInNAsBi, and GaInNAsSbBi as a dilute nitride.

11. The process according to claim 1 wherein
the n+ layer is selected from the group consisting of gallium arsenide, aluminum indium gallium phosphide, indium gallium phosphide, aluminum gallium arsenide, gallium indium arsenide, and aluminum gallium indium arsenide phosphide;
the p+ layer is selected from the group consisting of gallium arsenide, aluminum indium gallium phosphide, indium gallium phosphide, aluminum gallium arsenide, gallium indium arsenide, and aluminum gallium indium arsenide phosphide; and
the rare earth-Group V interlayer is selected from the group of erbium arsenide and erbium phosphide.

12. A III-V compound-type multi junction solar cell having at least one sub-cell, the solar cell comprising:
a) a junction structure having:
an n+ semiconductor layer;
a p+ semiconductor layer; and
a rare earth-Group V interlayer between the p+ layer and the n+ layer that forms a mid-gap-state-assisted assisted tunnel diode;
b) at least one layer containing a dilute nitride,
c) wherein the solar cell has been subjected to thermal energy sufficient to modify the dilute nitride containing layer.

13. The solar cell according to claim 12 wherein the annealing step is sufficient to modify voltage and current properties of the dilute nitride layer.

14. The solar cell according to claim 12 wherein the n+ layer is a III-V-based compound.

15. The solar cell according to claim 14 wherein the p+ layer is a III-V-based compound.

16. The solar cell according to claim 15 wherein the rare earth-Group V interlayer is a compound of a lanthanide and a Group V element.

17. The solar cell according to claim 15 wherein the rare earth-Group V interlayer

18. The solar cell according to claim 12 wherein the n+ layer is a dilute nitride.

19. The solar cell according to claim 12 wherein the n+ layer is selected from the group consisting of GaInNAs, GaInNAsSb, GaInNAsBi, and GaInNAsSbBi as a dilute nitride.

20. The solar cell according to claim 12 wherein the p+ layer is a dilute nitride.

21. The solar cell according to claim 12 wherein the p+ layer is selected from the group consisting of GaInNAs, GaInNAsSb, GaInNAsBi, and GaInNAsSbBi as a dilute nitride.

22. The solar cell according to claim 12 wherein the n+ layer is selected from the group consisting of gallium arsenide, aluminum indium gallium phosphide, indium gallium phosphide, aluminum gallium arsenide, gallium indium arsenide, and aluminum gallium indium arsenide phosphide;
the p+ layer is selected from the group consisting of gallium arsenide, aluminum indium gallium phosphide, indium gallium phosphide, aluminum gallium arsenide, gallium indium arsenide, and aluminum gallium indium arsenide phosphide; and
the rare earth-Group V interlayer is selected from the group of erbium arsenide and erbium phosphide.
